(19) United States
(12) Patent Application Publication
(10) Pub. No.: US 2015/0002189 A1
(43) Pub. Date: Jan. 1, 2015

(54) CENTRAL INPUT BUS TERMINATION TOPOLOGY

(71) Applicant: TEXAS INSTRUMENTS DEUTSCHLAND GMBH, Freising (DE)

(72) Inventors: Markus DIETL, Munich (DE); Sotirios TAMBOURIS, Munich (DE); Erich BAYER, Thonhausen (DE); Maurizio SKERLJ, Munich (DE)

(21) Appl. No.: 13/931,492

(22) Filed: Jun. 28, 2013

(51) Int. Cl. H03K 19/00

(52) U.S. Cl. CPC H03K 19/0013
USPC 326/30

(57) ABSTRACT

An input bus termination (IBT) system for an integrated circuit that includes a termination switch coupled to a plurality of input lines of an integrated circuit, each of the plurality of input lines coupled to a common node of the termination switch through a resistor, wherein the termination switch is to generate a termination voltage at the common node based on the composite potential generated by the plurality of input lines at the common node when an input signal is received across the plurality of input lines.

### CROSS-REFERENCE TO RELATED APPLICATION

None.

### BACKGROUND

Conventional integrated circuits (ICs) with multiple, asynchronous, resistor-terminated inputs may require a certain resistance to be maintained on the input pins for proper data transmission into the IC. The power used to maintain proper resistance may tend to add to the overall power consumption of the IC without adding to the ICs functional processing. The entire electronics industry is searching for areas to reduce power consumption and power consumption that does not necessarily add to the function of a device may be a prime target.

### SUMMARY

The problems noted above are solved in large part by an input bus termination (IBT) system for an integrated circuit that includes a termination switch coupled to a plurality of input lines of an integrated circuit, each of the plurality of input lines coupled to a common node of the termination switch through a resistor, wherein the termination switch is to generate a termination voltage at the common node based on the composite potential generated by the plurality of input lines at the common node when an input signal is received across the plurality of input lines.

Another embodiment is a termination switch that includes a first circuit coupled between a common node and a source voltage, a second circuit coupled between the common node and a ground, a capacitor coupling the common node to the ground, and a plurality of input lines coupled to the common node through a plurality of resistors. Wherein the first circuit of the termination switch is to increase a termination voltage at the common node when the termination voltage falls below a first threshold voltage and the second circuit of the termination switch is to decrease the termination voltage at the common node when the termination voltage rises above a second threshold voltage.

And yet another embodiment is a method to maintain a desired termination voltage on input pins of an integrated circuit that includes detecting a voltage at a common node connected to a plurality of input lines, increasing the voltage at the common node when the voltage at the common node falls below a first threshold voltage, and decreasing the voltage at the common node when the voltage at the common node rises above a second threshold voltage.

### BRIEF DESCRIPTION OF THE DRAWINGS

For a detailed description of exemplary embodiments of the invention, reference will now be made to the accompanying drawings in which:

FIG. 1 shows a multiple input IC;

FIG. 2 shows an example of a conventional IBT topology for a multiple input IC;

FIG. 3 is a circuit diagram of an example termination switch in accordance with various examples; and

FIG. 4 shows a method for adjusting a common node potential for a multiple, resister-terminated input IC in accordance with various embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

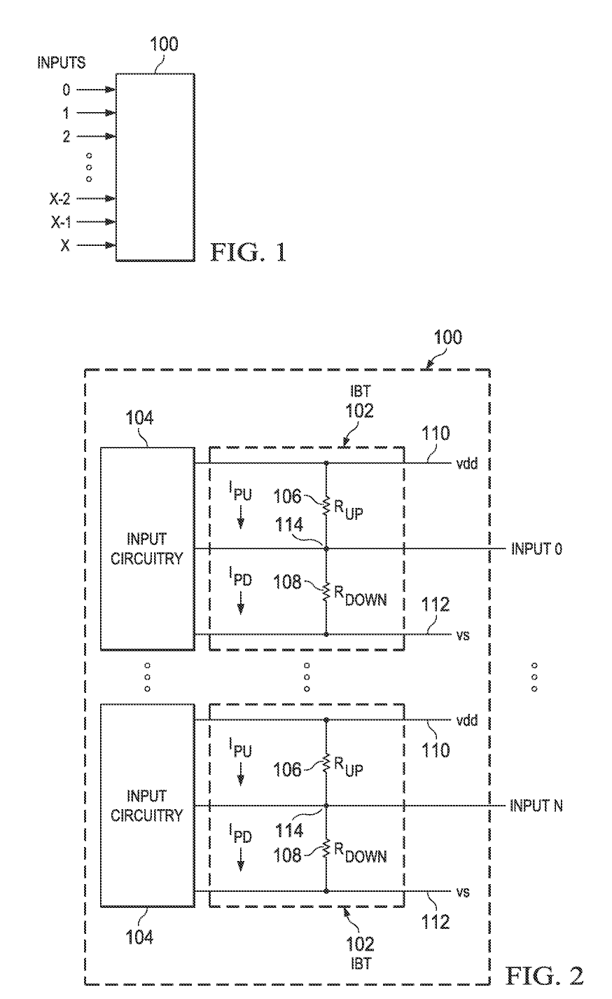

ICs designed with multiple, asynchronous, resistor-terminated input lines, see IC 100 of FIG. 1 for example, may use a specific potential on the input pin or node for proper transmission and receipt of data. This potential, the input bus termination (IBT), and the maintenance of the potential by the IC may consume large amounts of power without adding to the overall effectiveness of the IC. The IC 100 may require all input pins to maintain the desired potential so that the transmission lines that terminate on the input pins 0 through x remain at a constant potential. The desired potential may be a portion of the IC's supply voltage, Vdd, i.e., Vdd/2, Vdd/3, etc. The potential on the input pins, however, may fluctuate when data is received by the IC 100. For example, if a high voltage represents a “1” and a low voltage represents a “0,” then receiving a “1” on a pin may drive the input node potential above the set potential. This higher potential may then be dissipated to bring the node back to the required potential. When a “0” is received, the node may be driven higher in response. Alternatively and within the scope of this disclosure, a “1” may be represented by a low voltage and a “0” may be represented by a high voltage. This process of regulating the input pin potential may be carried out at each pin due to the received data.

The IBT's associated with each pin consume a lot of power in response to maintaining the set potential. Further, since each input pin has an associated IBT, the power consumption scales with the number of input pins. Thus, ICs with multiple, asynchronous, resistor-terminated input lines tend to be power hungry.

FIG. 2 shows an example of a conventional IBT topology for a multiple input IC. The IC may comprise N inputs, input 0 through input N, with each input connected to an input circuitry 104. Also associated with each of the N inputs is an IBT 102. The IBT 102 topology may be a voltage divider circuit connecting the input to a power supply Vdd and a power supply Vss. The power supply Vss, alternatively, may be a common ground. The IBT 102 may comprise an R_{UP} resister 106 and an R_{DOWN} resistor 108.

The voltage divider may be designed to keep a node 114, which is between R_{UP} and R_{DOWN}, at a specific potential, such as Vdd/2. When the potential at the node 114 changes, current may begin to flow in the voltage divider circuit to restore the desired potential. For example, if the voltage at node 114 drops due to incoming data on the input being a “1,” then current I_{PD} may begin to flow through R_{DOWN} to decrease the voltage at the node 114. In the opposite situation where the input is a “0,” then current I_{PU} may begin to R_{UP} to increase the voltage at the node 114. In both scenarios, the current may cease flowing once Vdd/2 is obtained at the node 114. Further, in both scenarios, the current flowing in the IBT 102 is through current going from Vdd to Vss meaning the current and power is only used to maintain the voltage at the node 114 and is not used for any of the processing of the data because the current passes through to ground and is thus consumed by each input pin of the IC 100.

Disclosed herein are a device, a system, and a method to decrease the power consumption of ICs with multiple, asynchronous, resistor-terminated input lines. The reduction of power consumption may comprise an IBT topology that couples all input lines of an IC to a single common node associated with a termination switch. The termination switch may be used by all input lines of the IC. The termination switch may include logic used to increase and/or decrease the voltage at the common node so that it remains at a desired level. The termination switch may supply current from Vdd or to Vss depending on the input data received on the input lines of the IC. An equal mixture of “1s” and “0s” on the input lines may not require any power consumption. Unequal mixtures of “1s” and “0s” may cause the consumption of power. The amount of power consumed by an IC in the uneven mixture scenario may be about 50% or less of the power consumed by a conventional IBT topology.

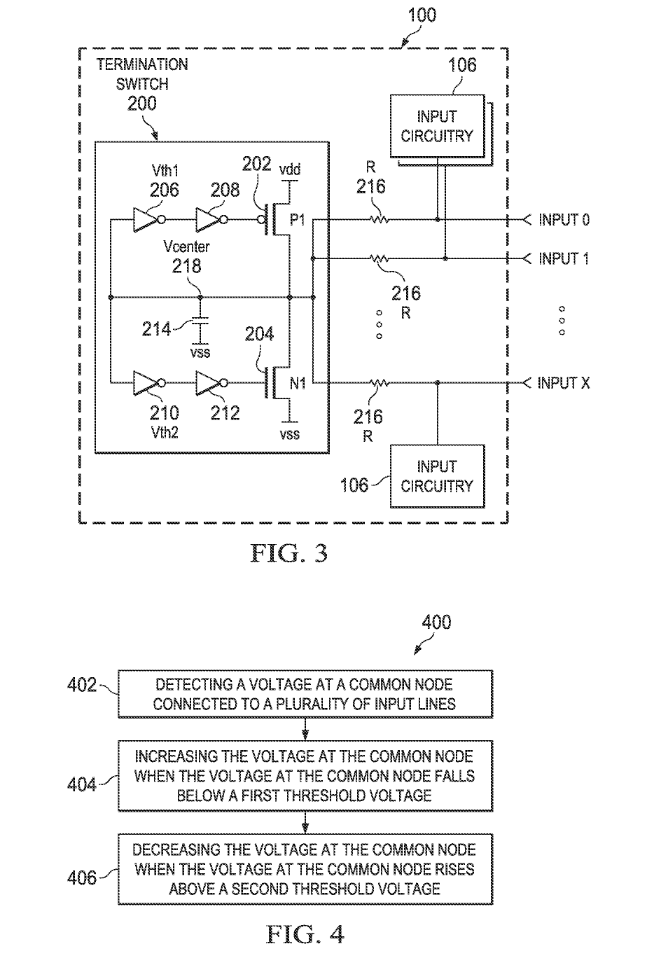

FIG. 3 is a circuit diagram of an example termination switch 200 in accordance with various examples as discussed herein. The termination switch 200 (the termination switch 200 may also be referred to as IBT topology 200) may be included in a multiple, resistor-terminated input IC such as the IC 100. The N inputs to the IC 100 may terminate at a plurality of resistors 216, which may all be coupled together and coupled to a common node, a Vcenter 218 node. Each of the N resistors 216 may be of equal value or, alternatively, the N resistors 216 may be of varying values. As will be discussed below, a driving factor for the termination switch is the composite amount of current that is received on the inputs by the IC 100 when data arrives and the potential generated at the Vcenter 218. The composite current's effect on the Vcenter 218 potential may determine if the termination switch is activated.

The termination switch 200 may include two similar circuits mirrored across a common node, such as the Vcenter 218. One circuit may connect the Vcenter 218 to Vdd and the other circuit may connect the Vcenter 218 to Vss or a common ground. The circuit connecting Vcenter 218 to Vdd may comprise a PMOS transistor 202, an inverter 206 and an inverter 208. The transistor 202's source may be coupled to Vdd and the transistor 202's drain may be coupled to the Vcenter 218. An input to the inverter 206 may be coupled to the Vcenter 218 with the inverter 206's output coupled to an input of the inverter 208. An output of the inverter 208 may be coupled to a gate of the transistor 202. The circuit connecting Vcenter to Vss may mirror the circuit just described.

The second circuit may comprise a NMOS transistor 204 with its source coupled to the Vcenter 218 and its drain coupled to Vss. An inverter 210 may have an input coupled to the Vcenter and an output coupled to an input of an inverter 212. An output of the inverter 212 may be coupled to the gate of the transistor 204. Further, the Vcenter 218 node may also be coupled to Vss or ground through a capacitor 214. The two inverters 206 and 210 may have their threshold voltages set to be below (inverter 206) and above (inverter 210) the set potential for the Vcenter 218. The termination switch 200 may function so that the potential at the Vcenter 218 is at a constant level, such as Vdd/2. Other desired potentials, such as Vdd/3, may also be covered by this disclosure. If the Vcenter 218 node is to remain at Vdd/2, then the threshold voltage Vth1 of the inverter 206 may be set less than Vdd/2. The threshold voltage Vth2 of the inverter 210 may be set higher than Vdd/2.

The potential at the Vcenter 218 node may be affected by incoming data on the N inputs of the IC 100. The N inputs may either receive a “1” corresponding to a high voltage, for example, or a “0” corresponding to a low voltage or zero voltage. Depending on the data coming into the IC 100, the N inputs may have different numbers of lines at a “1” and at a “0.” The various scenarios for the inputs, however, may be sorted into three general categories—an even distribution of “1s” and “0s,” more “1s” than “0s,” and more “0s” than “1s”. These three scenarios correspond to three operating conditions of the termination switch 200. For example, if the input currents generate a potential at the Vcenter 218 that pulls the Vcenter 218 below Vth1 (this may correspond to more “0s” than “1s,” but may also be implementation dependent), then the transistor 202's gate may receive a voltage via the inverter 208 effectively turning the transistor 202 “on.” With the transistor 202 in the on state, the transistor 202 begins to flow current into the Vcenter 218 node thereby adding charge to the capacitor 214. The added charge in the capacitor 214 may then increase the potential at the Vcenter 218, which may continue until the potential at the Vcenter 218 exceeds Vth1. Once the potential at the Vcenter 218 rises above Vth1, the transistor 202 turns off and the voltage at the Vcenter 218 may settle to Vdd/2 with the added voltage from the N inputs.

For the scenario when the input potential distribution pulls the Vcenter 218 above Vth2 (this may correspond to more “1s” than “0s,” but may also be implementation dependent), then the inverter 210 may begin to conduct, which effectively turns on the transistor 204 via the inverter 212. When the transistor 204 is conducting, the capacitor 214 may begin to flow current to the Vss, which decreases the potential at the Vcenter 218 node. Once the potential at Vcenter 218 drops below Vth2, the transistor 204 shuts off and current ceases to flow. Once current stops flowing, the potential at the Vcenter 218 node may settle to Vdd/2.

For the last scenario, the input potential distribution may be such that the potential at the Vcenter 218 remains between Vth1 and Vth2. A Vcenter 218 potential value between Vth1 and Vth2 may not activate the termination switch 200 and the Vcenter 218 potential may remain at Vdd/2 due to the input potential distribution. This scenario may correspond to roughly an equal number of “1s” and “0s” if the N resistors 216 have the same value, or a situation where the potential generated by the inputs stays within Vth1 and Vth2 regardless of the resistance values of the N resistors 216.

The potential generated at the Vcenter 218 by the inputs may be affected by the pattern or distribution of “1s” and “0s” and/or by the differences in the resistor 216 values of the N inputs. In either light, the potential generated by the input and whether or not that potential falls below Vth1 or rises above Vth2 may determine if the termination switch 200 activates to adjust the voltage at the Vcenter 218 to the desired level of Vdd/2.

The two threshold voltages, Vth1 and Vth2, may be set based on a tradeoff between power consumption and tolerance for fluctuations in the potential at the Vcenter 218 node. Fluctuations in the potential at the Vcenter 218 node may affect the design tolerances of the N resistors 216 and the capacitor 214. By selecting a Vth1 and a Vth2 that are far away from Vdd/2, the termination switch 200 may be activated less often due to the potential at Vcenter 218 remaining in between the two values even for large changes due to the input distribution potential. In this design paradigm, the IC 100 may dissipate less power but may require larger tolerances for the N resistors 216 and the capacitor 218. On the other end with Vth1 and Vth2 close to Vdd/2, the termination switch 200 may be activated more often leading to the IC 100 consuming more power. Regardless of either design choice, the termination switch 200 may consume 50% less power than the IBT 102 of FIG. 1 leading to a large power savings.

FIG. 4 shows a method 400 for adjusting a common node potential for a multiple, resister-terminated input IC in accordance with various embodiments as discussed herein. The method 400 begins as step 402 with detecting a voltage at a common node connected to a plurality of input lines. The voltage at the common node may be detected by a termination switch 200 and is measured by logic to determine whether or not the voltage is within a range around a desired level, such as Vdd/2.

The method 400 continues at step 404 with increasing the voltage at the common node when the voltage at the common node falls below a first threshold voltage. The decrease in the common node voltage may correspond to the potential at the Vcenter 218 node dropping below Vth1, the first threshold voltage. As described above, when the potential at Vcenter 218 drops below Vth1, the transistor 202 begins to flow current into the Vcenter 218 node to increase the node voltage above the Vth1 by charging the capacitor 214, and to settle onto Vdd/2. The termination switch 200 may only flow enough current to reach Vdd/2 before shutting off. Such operation may reduce the power consumption of the IC 100.

The method 400 ends at step 406 with decreasing the voltage at the common node when the voltage at the common node rises above a second threshold voltage. This step may correspond to the termination switch 200 draining charge from the capacitor 214 to decrease the potential at the Vcenter 218 back down to Vdd/2. Again, the termination switch 200 may only flow current out of the capacitor 214 to ground until the Vcenter 218 reaches Vdd/2. As such, only a minimal amount of current and power is consumed to adjust the Vcenter 218 down to Vdd/2.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An input bus termination (IBT) system for an integrated circuit, comprising:
a termination switch coupled to a plurality of input lines of an integrated circuit, each of the plurality of input lines coupled to a common node of the termination switch through a resistor, wherein the termination switch is to generate a termination voltage at the common node based on the composite potential generated by the plurality of input lines at the common node when an input signal is received across the plurality of input lines.

2. The IBT system of claim 1, wherein the termination switch comprises:
a first circuit to increase the voltage at the common node when the composite potential falls below a first threshold voltage.

3. The IBT system of claim 2, wherein the termination switch further comprises:
a second circuit to decrease the voltage at the common node when the composite potential rises above a second threshold voltage.

4. The IBT system of claim 3, wherein the first and second circuits are coupled together at the common node.

5. The IBT system of claim 4, further comprising a capacitor that couples the common node to a ground or a common power supply line.

6. The IBT of claim 4, wherein the termination voltage is between the first and second threshold voltages.

7. The IBT system of claim 1, wherein the resistors coupling each of the plurality of input lines to the common node are of equal resistance values.

8. The IBT of claim 1, wherein the termination voltage is one-half the supply voltage.

9. A termination switch, comprising:
a first circuit coupled between a common node and a source voltage;
a second circuit coupled between the common node and a ground;
a capacitor coupling the common node to the ground; and
a plurality of input lines coupled to the common node through a plurality of resistors;
wherein the first circuit is to increase a termination voltage at the common node when the termination voltage falls below a first threshold voltage and the second circuit is to decrease the termination voltage at the common node when the termination voltage rises above a second threshold voltage.

10. The termination switch of claim 9, wherein the first circuit comprises:
an input of a first inverter coupled to the common node and an output of the first inverter coupled to an input of a second inverter, wherein the first inverter begins to operate when the termination voltage falls below the first threshold voltage;
an output of the second inverter coupled to a gate of a first transistor;
a source of the first transistor coupled to the source voltage; and
a drain of the first transistor coupled to the common node;
wherein the first circuit begins to flow current into the capacitor when the first inverter begins to operate and the flow of current into the capacitor increases the termination voltage to a mid-point between the first and second threshold voltages; and
wherein the first circuit stops flowing current when the termination voltage reaches the mid-point between the first and second threshold voltages.

11. The termination switch of claim 9, wherein the second circuit comprises:
an input of a third inverter coupled to the common node and an output of the third inverter coupled to an input of a fourth inverter, wherein the third inverter begins to operate when the termination voltage rises above the second threshold voltage;
an output of the fourth inverter coupled to a gate of a second transistor;
a source of the second transistor coupled to the ground; and
a drain of the second transistor coupled to the common node;
wherein the second circuit begins to flow current out of the capacitor when the third inverter begins to operate and the flow of current out of the capacitor decreases the termination voltage to a mid-point between the first and second threshold voltages; and
wherein the second circuit stops flowing current when the termination voltage reaches the mid-point between the first and second threshold voltages.

12. The termination switch of claim 9, wherein the termination voltage is half the source voltage.

13. The termination switch of claim 9, wherein the resistance values of the plurality of resistors may be changed.

14. The termination switch of claim 9, wherein the termination voltage falls below the first threshold voltage when more than half the plurality of input lines contain a zero input.

15. The termination switch of claim 9, wherein the termination voltage rises above the second threshold voltage when more than half the plurality of input lines contain a one input.

16. The termination switch of claim 9, wherein the termination voltage does not fall below the first threshold voltage or rise above the second threshold voltage when an equal number of input lines contain a zero and a one.

17. A method to maintain a desired termination voltage on input pins of an integrated circuit, comprising:
detecting a voltage at a common node connected to a plurality of input lines;
increasing the voltage at the common node when the voltage at the common node falls below a first threshold voltage; and
decreasing the voltage at the common node when the voltage at the common node rises above a second threshold voltage.

18. The method of claim 17, wherein the voltage at the common node falls below the first threshold voltage due to a composite voltage on the plurality of input lines going low due to a larger number of input lines being a zero than being a one.

19. The method of claim 17, wherein the voltage at the common node rises above the second threshold voltage due to a composite voltage on the plurality of input lines going high due to a larger number of input lines being a one than being a zero.

20. The method of claim 17, wherein the voltage at the common node is not changed when an equal number of input lines are ones and zeros.
